(19) United States
(12) Patent Application Publication
(10) Pub. No.: US 2025/0343011 A1
(43) Pub. Date: Nov. 6, 2025

(54) CAPACITOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chun-Chieh LU, Taipei City (TW); Georgios VELLIANITIS, Heverlee (BE); Yu-Ming LIN, Hsinchu City (TW)

(73) Assignee: TAIWAN SEMICONDUCTOR MANUFACTURING COMPANY, LTD., Hsinchu (TW)

(21) Appl. No.: 18/652,764

(22) Filed: May 1, 2024

(51) Int. Cl. H01G 7/06; G11C 11/22; H01L 29/92; H10B 53/30

(52) U.S. Cl. CPC H01G 7/06; H10B 53/30; H10D 1/62; G11C 11/221

(57) ABSTRACT

A capacitor structure includes a bottom electrode, a top electrode, and a multilayer stack disposed between the bottom electrode and the top electrode. The multilayer stack has a capacitance value switchable between at least two capacitance states. The multilayer stack includes a ferroelectric layer over the bottom electrode, and an oxide semiconductor layer over the ferroelectric layer.

### BACKGROUND

Artificial neural networks (ANN) are one of the main tools used in machine learning, inspired by animal brains. A neural network consists of input and output layers. In common ANN implementations, the signal at a connection between artificial neurons is a real number, and the output of each artificial neuron is computed by some non-linear function of the sum of its inputs. The connections between artificial neurons are called “synapses”. Artificial neurons and synapses typically have a “weight” that adjusts as learning proceeds. The weight increases or decreases indicating an increase or decrease of the strength of the signal at a connection between two neurons. Artificial neurons may have a threshold such that the signal is only sent if the aggregate signal crosses that threshold. Typically, artificial neurons are aggregated into layers. Different layers may perform different kinds of transformations on their inputs. Signals travel from the first layer (the input layer) to the last layer (the output layer), possibly after traversing the layers multiple times.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a neural network in accordance with some embodiments.

FIG. 2 is a circuit diagram of a neural network in accordance with some embodiments.

FIG. 3 illustrates a schematic perspective view of an example of weight matrix of a neural network in accordance with some embodiments of the present disclosure.

FIG. 4 illustrates a cross-sectional view of an example capacitive synaptic cell of a neural network in accordance with some embodiments of the present disclosure.

FIGS. 5A and 5B are graphs illustrating capacitance-voltage (C-V) simulation results of ferroelectric capacitors (FeCAPs) having different material compositions, in accordance with some embodiments of the present disclosure.

FIG. 6 is a graph illustrating endurance tests conducted on FeCAPs having different material compositions, in accordance with some embodiments of the present disclosure.

FIGS. 7-15 illustrate cross-sectional views of intermediate stages in formation of an example integrated circuit (IC) structure having a capacitive synaptic cell (e.g., FeCAP) in accordance with some embodiments of the present disclosure.

FIG. 16 is a cross-sectional view of an integrated circuit structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

Embodiments of the present disclosure are applicable to compute-in-memory, processing-in-memory, processing-using-memory, near-memory-compute, near-data processing, near-memory processing, in-storage processing, GPU accelerator, TPU accelerator, In-memory computing, in-memory-processing, compute near memory, and/or processing near memory.

In the realm of compute-in-memory (CIM) technology such as deep learning algorithms, vector-matrix multiplications are employed. These algorithms often leverage the concept of “resistive weight” in analog memory systems, which uses non-volatile memory devices. Traditional designs, such as the 1T-1R (one transistor-one resistor) configuration, are being reevaluated in favor of architectures like the ferroelectric capacitor (FeCAP) crossbar array. FeCAPs stand out due to their numerous advantages, including significantly enhanced power efficiency, rapid operation capabilities (in the nanosecond range), compactness in terms of area, high data retention, and operation at low voltages.

By selecting different metal materials for the top and bottom electrodes of FeCAPs, the capacitance-voltage (C-V) curve can be adjusted. This adjustment leads to a shift relative to OV and opens up a window of non-zero capacitance at DC OV. Despite these advancements, there is a limitation in the memory window (MW) of FeCAPs, typically in the range of 5 to 6, which could potentially impact their retention performance. This is especially true in applications where data is stored and accessed over extended periods without degradation, such as in applications involved in lifelong or continual machine learning (ML).

Addressing this, embodiments of the present disclosure introduces an improved material design for ferroelectric capacitors (FeCAPs) that significantly enhances the memory window (MW) to be greater than, e.g., 10. The improved FeCAP material design includes a multilayer stack between FeCAP top electrode and FeCAP bottom electrode, wherein the multilayer stack includes one or more of an oxide semiconductor layer, a high-k dielectric layer, and a ferroelectric layer having a crystalline structure with a tetragonal crystalline phase and an orthorhombic crystalline phase. By achieving an MW greater than 10, as opposed to the typical range of 5 to 6, this design opens up the possibility of achieving superior retention performance. Such an improvement in the memory window is a significant advancement, as it directly impacts the longevity and reliability of the memory elements in machine learning and other data-intensive applications. This development holds significant potential for advancing the efficiency and effectiveness of memory devices in the context of ML and beyond. Moreover, these materials can be formed in low-temperature deposition processes, which can be integrated into back-end-of-line (BEOL) processing for embedded memory application.

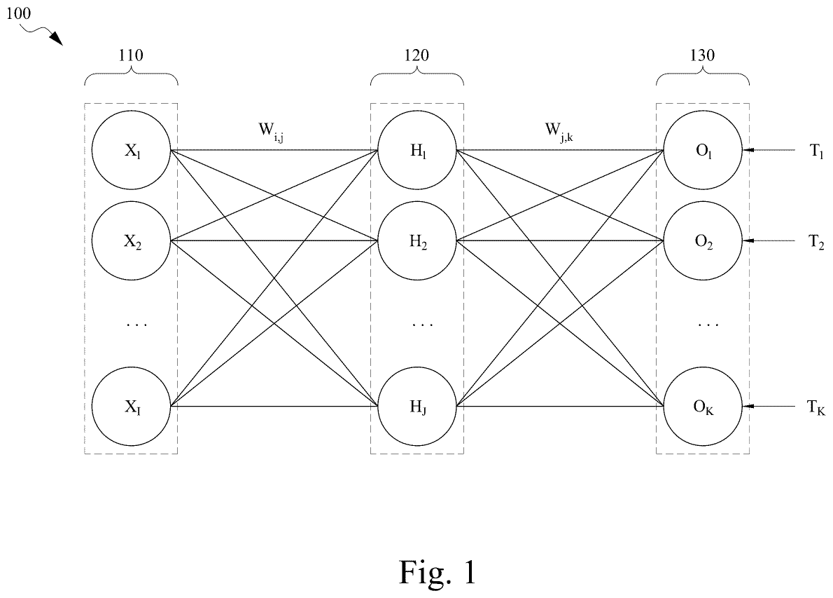

FIG. 1 is a block diagram of a neural network 100 in accordance with some embodiments. The neural network 100 includes an input neuron layer 110, one or more hidden neuron layers 120, and an output neuron layer 130. The input neuron layer 110 includes a plurality of neurons X₁-X_{I}, the hidden neuron layer 120 includes a plurality of neurons H₁-H_{J}, and the output neuron layer 130 includes a plurality of neurons O₁-O_{K}. These neurons are also referred to as electronic neurons that can be implemented using digital logic circuits made up of transistors. These circuits perform arithmetic, e.g., multiplication for weighted inputs, and addition for summing the weighted inputs. In some embodiments, two adjacent neuron layers are referred to as pre-neuron and post-neuron layers along a forward propagation direction. Each neuron in these layers is connected to multiple neurons in the subsequent layer by using synapses. For example, the neuron X₁ in the input neuron layer 110 is connected to each of the neurons H₁-H_{J} by using respective synaptic cells (i.e., straight lines illustrated in FIG. 1), the neuron X₂ in the input neuron layer 110 is also connected to each of the neurons H₁-H_{J} by using respective synaptic cells, and each of the rest neurons X_{I} in the input neuron layer 110 is also connected to all of the neurons H₁-H_{J} by using respective synaptic cells. The synaptic cells serve as connections to connect a neuron in a pre-neuron layer to a neuron in a post-neuron layer. In some embodiments, the synaptic cells are FeCAPs having programmable capacitance states or values.

In some embodiments, the input neuron layer 110 and the hidden neuron layer 120 are two adjacent neuron layers, and input data are inputted from the input neuron layer 110 to the hidden neuron layer 120. The input data is transformed into a binary number or other suitable digital type. Subsequently, the binary number is inputted into the neurons X₁-X_{I} of the input neuron layer 110. Each neuron in the input neuron layer 110 is connected with each neuron in the hidden neuron layer 120 by using various synaptic cells each having a synaptic weight W_{i,j}. For instance, the neuron X₁ in the input neuron layer 110 and the neuron H₁ in the hidden neuron layer 120 are connected by a synaptic cell having a synaptic weight W_{1,1}. Each of the neurons H₁-H_{J} in the hidden neuron layer 120 receives products of every input data and the weight W_{i,j}, and the product is referred to as a weighted sum in some embodiments.

In various embodiments, the hidden neuron layer 120 and the output neuron layer 130 are two adjacent neuron layers, and the input data are inputted from the hidden neuron layer 120 to the output neuron layer 130. Each neuron in the hidden neuron layer 120 is connected with each neuron in the output neuron layer 130 by using various synaptic cells each having a weight W_{j,k}. For instance, the neuron H2 in the hidden neuron layer 120 and the neuron O₂ in the output neuron layer 130 are connected using a synaptic cell having a weight W_{2,2} between the neuron H₂ and the neuron O₂. The weighted sum from each of the neurons H₁-H_{J} in the hidden neuron layer 120 serves as an input of the output neuron layer 130. Each of the neurons O₁-O_{K} in the output neuron layer 130 receives products of every weighted sum and the weight W_{j,k}.

As illustratively shown in FIG. 1, the weight sum outputted from each of the neurons O₁-O_{K} of the output neuron layer 130 is regarded as an output of the neural network 100. The outputs from the neurons O₁-O_{K} are compared with target values T₁-T_{K}, respectively. If one of the outputs from the neurons O₁-O_{K} is different from the corresponding target value of the target values T₁-T_{K}, the weight W_{i,j} between the input neuron layer 110 and the hidden neuron layer 120 and the weight W_{j,k} between the hidden neuron layer 120 and the output neuron layer 130 are adjusted until the output and the corresponding target value are the same. In some embodiments, the target value is a predetermined value set to be corresponding to the input data, such that the weight between two adjacent neurons can be trained repeatedly to optimize the weight value.

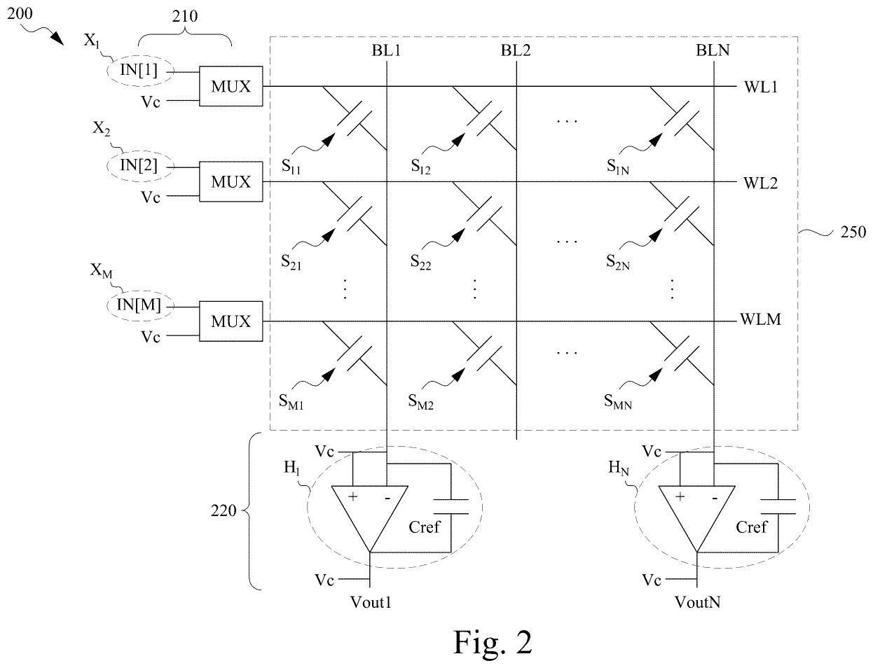

FIG. 2 is a circuit diagram of a neural network 200 in accordance with some embodiments. In some embodiments, the circuit diagram of the neural network 200 as described in FIG. 2 may be an exemplary circuit for implementing the neural network 100 as described in FIG. 1. The neural network 200 may include a pre-neuron layer 210 and a post-neuron layer 220 subsequent to the pre-neuron layer 210 and connected to the pre-neuron layer 210 by using a weight matrix 250. The pre-neuron layer 210 may be an input neuron layer similar to the input neuron layer 110 as discussed in FIG. 1, and the post-neuron layer 220 may be a hidden neuron layer similar to the hidden neuron layer 120 as illustrated in FIG. 1. In some embodiments, the pre-neuron layer 210 includes multiple neurons X₁, X₂ . . . , and X_{M}, and the post-neuron layer 220 includes multiple neurons H₁, H₂ . . . , and H_{N}. In some embodiments, the number “M” of neurons in the pre-neuron layer 210 is equal to the number “N” of neuron in the post-neuron layer 220. In some embodiments, the number “M” of neurons in the pre-neuron layer 210 is less than the number “N” of neuron in the post-neuron layer 220. In some embodiments, the number “M” of neurons in the pre-neuron layer 210 is greater than the number “N” of neurons in the post-neuron layer 220.

The weight matrix 250 includes a plurality of capacitive synaptic cells (e.g., FeCAPs) arranged in an array of rows and columns, a plurality of word lines coupled to first terminals of the capacitive synaptic cells, and a plurality of bit lines coupled to second terminals of the capacitive synaptic cells. For example, the neural network 200 has m number of neurons (i.e., X₁, X₂, . . . X_{M}) in the pre-neuron layer 210 respectively coupled to m number of word lines (i.e., WL1, WL2, . . . , and WLM), and n number of neurons (i.e., H₁, H₂, . . . H_{N}) in the post-neuron layer 220 respectively coupled to n number of bit lines (i.e., BL1, BL2, . . . , and BLN), and thus the weight matrix 250 includes m*n number of capacitive synaptic cells (i.e., S₁₁, S₁₂, . . . , S_{1N}, S₂₁, S₂₂ . . . , S_{2N}, . . . S_{M1}, S_{M2}, . . . , and SMN) arranged in an array of m number of rows and n number of columns. The synaptic cells are capacitors, instead of resistors. Capacitive synaptic cells utilize programmable capacitance states (at DC zero bias) as synaptic weights. Static power for the capacitive synaptic cells can be negligible as capacitors consume dynamic power only. Furthermore, open-circuit nature of a capacitor effectively blocks undesirable sneak-path current. It is noted that the access transistor in a one-transistor-one-resistor (1T1R) synaptic cell mainly serves to counter the sneak-path current. Because the capacitive synaptic cells have no or negligible sneak-path current, the capacitive synaptic cells can have no access transistor, which allows the capacitor of each synaptic cell having one terminal directly coupled to word line and one terminal directly coupled to bit line.

One example of operation of the neural network 200 includes two steps. In the first step, input WL voltages (i.e., IN[1], IN[2], . . . , IN[M]) propagate through respective WL multiplexers (denoted by “MUX” in FIG. 2) and charge the array of capacitive synaptic cells each having a corresponding ferroelectric capacitance (C_{FECAP}), which are preprogrammed to different capacitances to represent the values in the weight matrix. The product of one input WL voltage value and one weight capacitance value is encoded as the charges on each capacitive synaptic cell. Next, in the second step, the input voltages return to the common voltage (V_{C}) and become substantially the same as the negative input of the operational amplifiers (OPAMPs) in the neurons (i.e., H₁, H₂, . . . , and H_{N}) in the post-neuron layer 220. Therefore, the voltage drop on each capacitive synaptic cells becomes substantially 0 V so the charges are forced to transfer along the corresponding bit lines onto the reference capacitors C_{ref} in the neurons (i.e., H₁, H₂, . . . H_{N}) in the post-neuron layer 220. The number of charges on reference capacitors C_{ref} is the weighted sum along the bit line and the resulting output voltage (Vₒᵤₜ) serves as an input of a corresponding neuron (i.e., H₁, H₂, . . . , or H_{N}) in the post-neuron layer 220.

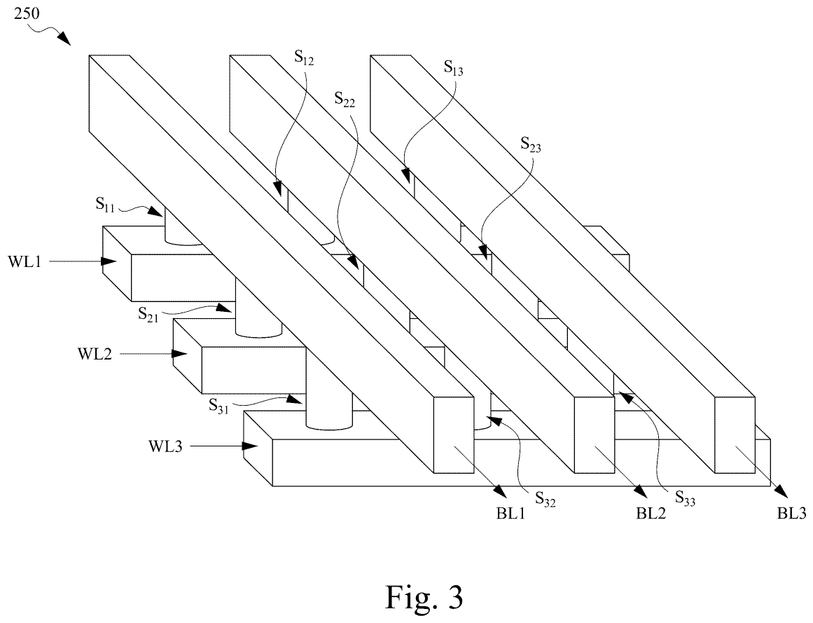

FIG. 3 illustrates a schematic perspective view of an example of weight matrix 250 in accordance with some embodiments of the present disclosure. In FIG. 3, the weight matrix 250 is configured in a crossbar array including word lines (e.g., WL1, WL2, and WL3) extending in a first direction, bit lines (e.g. BL1, BL2, and BL3) extending in a second direction perpendicular to the first direction, and capacitive synaptic cells (e.g., S₁₁, S₁₂, S₁₃, S₂₁, S₂₂, S₂₃, S₃₁, S₃₂, and S₃₃) each having a first terminal (e.g., bottom electrode) coupled to a corresponding one of word lines and a second terminal (e.g., top electrode) coupled to a corresponding one of bit lines.

In some embodiments, the capacitive synaptic cells (i.e., S₁₁, S₁₂, . . . , SIN, S₂₁, S₂₂ . . . , S_{2N}, . . . S_{M1}, S_{M2}, . . . , and S_{MN}) are ferroelectric capacitors (FeCAPs). The ferroelectric capacitors each have their programmable capacitance states or values to serve as synaptic weights. In the neural network 200 where the synaptic weights are represented by ferroelectric capacitors, each ferroelectric capacitor's capacitance state corresponds to the strength of a synaptic connection. The property of ferroelectric materials to exhibit hysteresis, meaning their polarization state, and thus capacitance, can be maintained without continuous power, which in turn allows these synaptic cells to store synaptic weights in a non-volatile memory manner. Synaptic weight of each capacitive synaptic cell can be changed during training of the neural network 100/200 by reprogramming the capacitance state of the corresponding ferroelectric capacitor by applying a suitable voltage pulse across the ferroelectric capacitor.

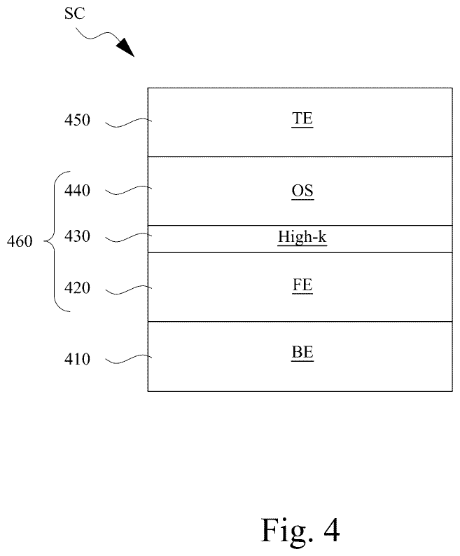

FIG. 4 illustrates a cross-sectional view of an example capacitive synaptic cell SC in accordance with some embodiments of the present disclosure. In FIG. 4, the capacitive synaptic cell SC is a ferroelectric capacitor (FeCAP), which includes a bottom electrode 410 (labeled “BE”), a ferroelectric layer 420 (labeled “FE”) over the bottom electrode 410, a high-k dielectric layer 430 (labeled “High-k”) over the ferroelectric layer 420, an oxide semiconductor layer 440 (labeled “OS”) over the high-k dielectric layer 430, and a top electrode 450 (labeled “TE”) over the oxide semiconductor layer 440. The ferroelectric layer 420, the high-k dielectric layer 430, and the oxide semiconductor layer 440 are collectively referred to as a capacitance-switchable multilayer stack 460. The capacitance-switchable multilayer stack 460 has a capacitance value switchable between at least two capacitance states.

In some embodiments, the bottom electrode 410 may be made of gold (Au), platinum (Pt), ruthenium (Ru), iridium (Ir), titanium (Ti), aluminum (Al), copper (Cu), tantalum (Ta), tungsten (W), iridium-tantalum alloy (Ir—Ta) or indium-tin oxide (ITO), or any alloy, oxide, nitride, fluoride, carbide, boride or silicide of these, such as TaN, TiN, TiAlN, TiW, combinations thereof, or the like.

In some embodiments, the ferroelectric layer 420 formed directly on the bottom electrode 410 has a crystalline structure formed of a mix of orthorhombic-phase (O-phase) and tetragonal-phase (T-phase) HfZrO (HZO). The use of a mixed orthorhombic/tetragonal-phase HZO in the ferroelectric layer 420 enhances the program-state capacitance due to the higher K-value (dielectric constant) of the tetragonal-phase HZO. The ferroelectric layer 420 is strategically engineered to leverage the distinct dielectric properties of both the orthorhombic and tetragonal phases of HZO. The orthorhombic-phase HZO contributes to the layer's stability and endurance, providing a robust base for the ferroelectric properties. In contrast, the inclusion of the tetragonal-phase HZO significantly elevates the dielectric constant of the ferroelectric layer 420, which directly translates to an improved capacitance in the program state. This mixed-phase composition not only optimizes the ferroelectric performance but also tailors the electrical properties of the layer to specific application requirements, e.g., requirements for neural network.

The ratio of orthorhombic-phase to tetragonal-phase HZO within the ferroelectric layer 420 is meticulously optimized based on the desired balance between stability and capacitance enhancement. For example, a higher ratio of tetragonal-phase HZO (e.g., with a ratio of T-phase to O-phase greater than 1) may be more suitable for the program-state capacitance improvement. By adjusting the fabrication parameters of the ferroelectric layer 420, such as the precursors' composition, deposition temperature, and/or annealing conditions of the ferroelectric layer 420, the phase composition within the ferroelectric layer 420 can be precisely controlled, which allows for the fine-tuning of the ferroelectric layer's properties to achieve the optimal balance between stability and capacitance based on the targeted application's specific requirements, e.g., requirements for neural network.

In some embodiments, the ferroelectric layer 420 is formed of a ferroelectric material with a spontaneous polarization, which can be reversed by an electric field applied by the bottom electrode 410 and/or the top electrode 450. In some embodiments, the ferroelectric material of the ferroelectric layer 420 includes HfZrO, HfAlO, HfLaO, HfCeO, HfO, HfGdO, HfSiO, or the like, with orthorhombic-phase (O-phase) crystals and tetragonal-phase (T-phase) crystals coexist in these selected materials. In some embodiments, the ferroelectric layer 420 includes more T-phase crystals than O-phase crystals to promote the program-state capacitance improvement. In some embodiments where the ferroelectric layer 420 is HfZrO, the atomic percentage of Zr is in a range from about 60% to 80%, which allows for achieving a desired T-phase to O-phase ratio, which is suitable for improving the program-state capacitance. In some embodiments, the ferroelectric layer 420 has a thickness in a range from about 2 nm to about 20 nm, and is deposited over the bottom electrode 410 by using any suitable method, e.g., chemical vapor deposition (CVD), plasma-enhanced CVD (PECVD), physical vapor deposition (PVD), atomic layer deposition (ALD), plasma-enhanced ALD (PEALD), or the like.

In some embodiments, the high-k dielectric layer 430 interposes the ferroelectric layer 420 and the oxide semiconductor layer 440 to serve as an interfacial layer between the ferroelectric layer 420 and the oxide semiconductor layer 440. The high-k dielectric layer 430 enhances the program-state capacitance due to its high-k value. In some embodiments, the high-k dielectric layer 430 can significantly stabilize the interface region between the ferroelectric layer 420 and oxide semiconductor layer 440, which improves long-term reliability and data retention of the synaptic cell SC. Fluctuations in the interface region between the ferroelectric layer 420 and the oxide semiconductor layer 440 due to chemical reactions, inter-diffusion, or stress can degrade the device performance of synaptic cell SC over time. The high-k dielectric layer 430 acts as a barrier that mitigates these effects, preserving the structural and electrical integrity of the interface region between the ferroelectric layer 420 and the oxide semiconductor layer 440.

In some embodiments, the high-k dielectric layer 430 has a thickness less than a thickness of the ferroelectric layer 420 and the oxide semiconductor layer 440. If the high-k dielectric layer 430 is excessively thick (e.g., thicker than the ferroelectric layer 420 and the oxide semiconductor layer 440), the forward sweep and/or reverse sweep for the synaptic cell SC may require excessively large voltage, leading to increased power consumption. In some embodiments, the thickness of the high-k dielectric layer 430 is in a range from about 0.1 nm to about 1 nm. In some embodiments, a thickness ratio of the ferroelectric layer 420 to the high-k dielectric layer 430 is in a range from about 2 to about 200.

In some embodiments, the high-k dielectric layer 430 is formed of a different material than the ferroelectric layer 420. For example, the high-k dielectric layer 430 includes Al₂O₃, HfO₂, ZrO₂, TiO₂, NbO, La₂O₃, or the like. In some embodiments, the high-k dielectric layer 430 is deposited over the ferroelectric layer 420 by using any suitable method, e.g., chemical vapor deposition (CVD), plasma-enhanced CVD (PECVD), physical vapor deposition (PVD), atomic layer deposition (ALD), plasma-enhanced ALD (PEALD), or the like.

In some embodiments, the oxide semiconductor layer 440 is disposed between the high-k dielectric layer 430 and the top electrode 450. The oxide semiconductor layer 440 allows for lowering the erase-state capacitance of the synaptic cell SC during the forward sweep performed on the synaptic cell SC. The unipolar carrier nature of the oxide semiconductor layer 440 contributes to this reduction, allowing for controlling the capacitance behavior in the forward sweep. In other words, if the synaptic cell SC is devoid of the oxide semiconductor layer 440, the erase-state capacitance of the synaptic cell SC may be undesirably high, which in turn degrades the memory window of the synaptic cell SC.

In some embodiments, the oxide semiconductor layer 440 includes metal oxide such as, ZnO, InWO, InGaZnO, InZnO, ITO, or the like. In some embodiments, the oxide semiconductor layer 440 has a thickness in a range from about 2 nm to about 20 nm, and is deposited over the high-k dielectric layer 430 by using any suitable method, e.g., chemical vapor deposition (CVD), plasma-enhanced CVD (PECVD), physical vapor deposition (PVD), atomic layer deposition (ALD), plasma-enhanced ALD (PEALD), or the like.

In some embodiments, the top electrode 450 is disposed over the oxide semiconductor layer 440. In some embodiments, the top electrode 450 may be formed from materials such as gold (Au), platinum (Pt), ruthenium (Ru), iridium (Ir), titanium (Ti), aluminum (Al), copper (Cu), tantalum (Ta), tungsten (W), iridium-tantalum alloy (Ir—Ta) or indium-tin oxide (ITO), or any alloy, oxide, nitride, fluoride, carbide, boride or silicide of these, such as TaN, TIN, TiAlN, TiW, combinations thereof, or the like. In some embodiments, the top electrode 450 is formed of a different material than the bottom electrode 410. By selecting different metal material for the top electrode 450 and the bottom electrode 410, the capacitance-voltage (C-V) curve of the synaptic cell SC can be further shifted, thus further increasing the memory window of the synaptic cell SC.

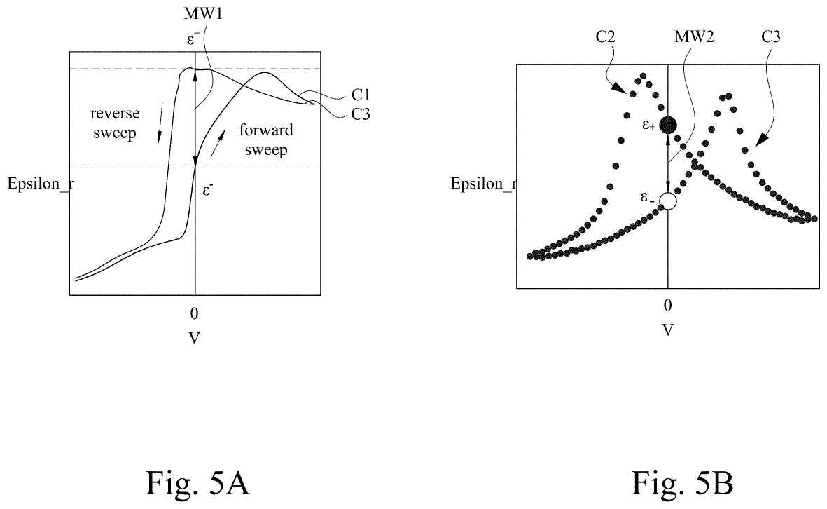

FIGS. 5A and 5B are graphs illustrating capacitance-voltage (C-V) simulation results of FeCAPs having different material compositions between FeCAP's top and bottom electrodes. FIG. 5A plots the capacitance-voltage (C-V) characteristics of the FeCAP including a stack of ferroelectric layer 420, high-k dielectric layer 430, and oxide semiconductor layer 440 between top and bottom electrodes. In FIG. 5A, the dielectric constant Er (epsilon) is shown on the vertical axis, and the voltage applied across the FeCAP is shown on the horizontal axis. The curve C1 represents a C-V characteristic resulting from forward sweep from a determined negative voltage to a determined positive voltage. The curve C2 represents a C-V characteristic resulting from reverse sweep (also referred to as backward sweep) from the determined positive voltage to the determined negative voltage. The forward sweep is associated with the “erase” or “reset” operation performed on the FeCAP memory device. This is because the applied voltage reorients the polarization of the ferroelectric material in the FeCAP, effectively resetting the state of the FeCAP to a baseline or “erased” state. The reverse sweep is associated with the “program” or “write” operation performed on the FeCAP memory device. By using the reverse sweep, the ferroelectric material is reversed or altered from its initial state to a specific polarization state, resulting in a different capacitance value compared to the forward sweep.

The curves C1 and C2 show asymmetric C-V characteristics, which show a high-capacitance state in the reverse sweep curve C2 and a low-capacitance state in the forward sweep curve C1 at DC OV. Here the dielectric constant (εᵣ) represents the capacitance states. The memory window MW1 of FeCAP refers the difference between dielectric constant ε₊ in the reverse sweep curve C2 (i.e., program state) and the dielectric constant ε− in the forward sweep curve C1 (i.e., erase state). In simulation results, the memory window MW1 is greater than 10. For example, the dielectric constant ε₊ in the reverse sweep curve C2 is in a range from about 31-34, and the dielectric constant ε− in the forward sweep curve C1 is in a range from about 19-20.

FIG. 5B plots the capacitance-voltage (C-V) characteristics of a reference FeCAP including a ferroelectric layer but devoid of a high-k dielectric layer 430 and an oxide semiconductor layer between reference FeCAP's top and bottom electrodes. In FIG. 5B, the dielectric constant εᵣ (epsilon) is shown on the vertical axis, and the voltage applied across the reference FeCAP is shown on the horizontal axis. The curve C3 represents a C-V characteristic resulting from forward sweep from a determined negative voltage to a determined positive voltage. The curve C4 represents a C-V characteristic resulting from reverse sweep (or called backward sweep) from the determined positive voltage to the determined negative voltage. The curves C3 and C4 show asymmetric C-V characteristics, which show a high-capacitance state in the reverse sweep curve C4 and a low-capacitance state in the forward sweep curve C3 at DC OV. Here the dielectric constant (εᵣ) represents the capacitance states. The memory window MW2 of the reference FeCAP refers the difference between dielectric constant ε₊ in the reverse sweep curve C4 and the dielectric constant ε− in the forward sweep curve C3. In simulation results, the memory window MW2 is in a range from 5 to 6, which is less than the memory window MW1 by about 40%-50%. The simulation results in FIGS. 5A and 5B indicate that the memory window can be significantly improved by disposing the stack of ferroelectric layer 420, high-k dielectric layer 430, and oxide semiconductor layer 440 between top and bottom electrodes.

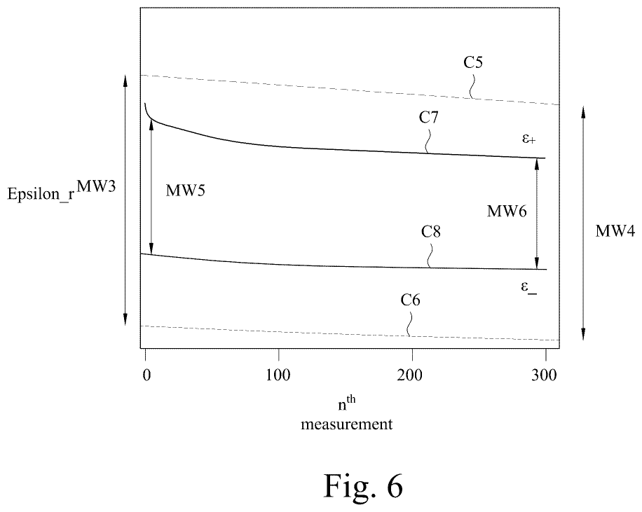

FIG. 6 is a graph illustrating endurance tests conducted on FeCAPs having different material compositions between FeCAP's top and bottom electrodes. This graph plots the dielectric constant εᵣ (epsilon) on the vertical axis against the measurement cycle count on the horizontal axis, providing insights into the durability of different FeCAP structures under repeated use. Curves C5 and C6 depict the variations in the program-state dielectric constant ε₊ and the erase-state dielectric constant ε−, respectively, of an FeCAP configured with a layered stack comprising a ferroelectric layer 420, a high-k dielectric layer 430, and an oxide semiconductor layer (440). These curves C5 and C6 illustrate the evolution of the memory window from an initial memory window MW3 to final memory window MW4 after 300 measurement cycles. Curves C7 and C8 represent the changes in the program-state dielectric constant and erase-state dielectric constant of a reference FeCAP, which lacks the high-k dielectric layer 430 and the oxide semiconductor layer 440. Similarly, these curves C7 and C8 track the memory window's progression from an initial memory window MW5 to a final memory window MW6 after 300 measurement cycles.

The comparative analysis reveals that the improved FeCAP with the ferroelectric, high-k dielectric, and oxide semiconductor layers demonstrates better endurance and data retention capabilities than the reference FeCAP. This is evidenced by the smaller difference between the initial and final memory windows MW3 to MW4 of the improved FeCAP compared to that between the initial and final memory windows MW5 to MW6 of the reference FeCAP. Furthermore, the final memory window MW4 of the improved FeCAP still exceeds a value of 10, surpassing the initial memory window MW5 of the reference FeCAP.

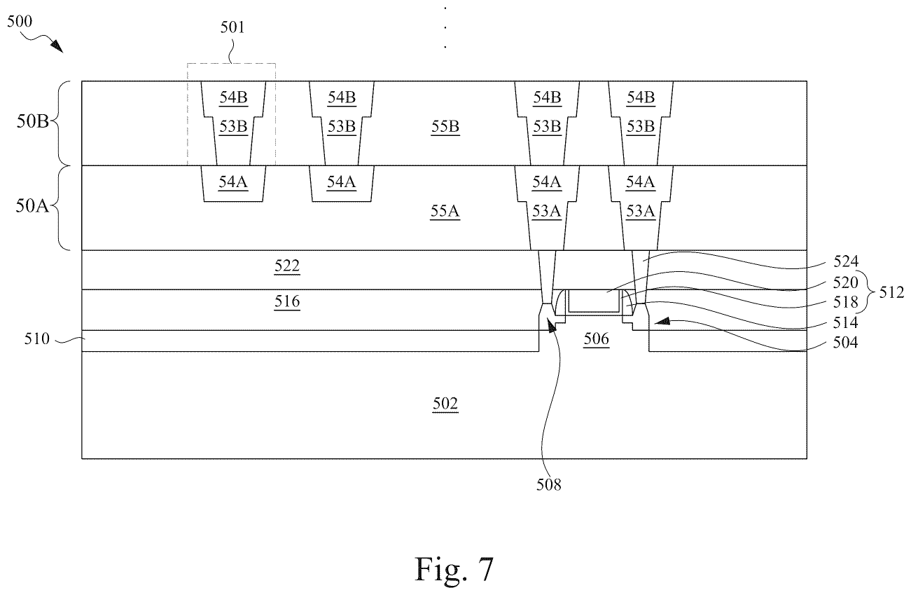

FIGS. 7-15 illustrate cross-sectional views of intermediate stages in formation of an example integrated circuit (IC) structure 500 having a capacitive synaptic cell (e.g., FeCAP) in accordance with some embodiments of the present disclosure. Although the cross-sectional views shown in FIGS. 7-15 are described with reference to a method, it will be appreciated that the structures shown in FIGS. 7-15 are not limited to the method but rather may stand alone separate of the method. Although FIGS. 7-15 are described as a series of acts, it will be appreciated that these acts are not limiting in that the order of the acts can be altered in other embodiments, and the methods disclosed are also applicable to other structures.

FIG. 7 illustrates a cross-sectional view of an example semiconductor structure 500 comprising a semiconductor substrate 502 in which various electronic devices may be formed, and a portion of a multilevel interconnect structure (e.g., layers 50A and 50B) formed over the substrate 502, in accordance with some embodiments. Generally, FIG. 7 illustrates a transistor 504 formed on the substrate 502, with multiple interconnection layers formed thereover. As indicated by the ellipsis at the top of FIG. 7, multiple interconnect levels may be similarly stacked in the fabrication process of an integrated circuit. As illustrated, the transistor 504 is a FinFET. In some other embodiments, the transistor 504 is a planar FET, a nanosheet FET, or other suitable FET. One or more transistors 504 can serve for logic circuits, static random access memory (SRAM) circuits, peripheral circuits, I/O circuits, and/or analog circuits.

The substrate 502 illustrated in FIG. 7 may comprise a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally comprise the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

The FinFET device 504 illustrated in FIG. 7 is a three-dimensional MOSFET structure formed in fin-like strips of semiconductor protrusions 506 referred to as fins. The cross-section shown in FIG. 7 is taken along a longitudinal axis of the fin in a direction parallel to the direction of the current flow between the source and drain regions 508. The fin 506 may be formed by patterning the substrate using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 506 by etching a trench into the substrate 502 using, for example, reactive ion etching (RIE). FIG. 7 illustrates a single fin 506, although the substrate 502 may comprise any number of fins.

Shallow trench isolation (STI) regions 510 formed along opposing sidewalls of the fin 506 are illustrated in FIG. 7. STI regions 510 may be formed by depositing one or more dielectric materials (e.g., silicon oxide) to completely fill the trenches around the fins and then recessing the top surface of the dielectric materials. The dielectric materials of the STI regions 510 may be deposited using a high density plasma chemical vapor deposition (HDP-CVD), a low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 510 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 510 such that an upper portion of fin 506 protrudes from surrounding insulating STI regions 510. In some cases, the patterned hard mask used to form the fin 506 may also be removed by the planarization process.

In some embodiments, the gate structure 512 of the FinFET device 504 illustrated in FIG. 6 is a high-k, metal gate (HKMG) gate structure that may be formed using a gate-last process flow. In a gate last process flow a sacrificial dummy gate structure (not shown) is formed after forming the STI regions 510. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 510. As described in greater detail below, the dummy gate structure may be replaced by the HKMG gate structure 512 as illustrated in FIG. 6. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

Source and drain regions 508 and spacers 514 of FinFET 504, illustrated in FIG. 7, are formed, for example, self-aligned to the dummy gate structures. Spacers 514 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 514 along the sidewalls of the dummy gate structures.

Source and drain regions (also collectively referred to as source/drain regions or S/D regions) 508 are semiconductor regions in direct contact with the semiconductor fin 506. In some embodiments, the source and drain regions 508 may comprise heavily-doped regions and relatively lightly-doped drain extensions, or LDD regions. Generally, the heavily-doped regions are spaced away from the dummy gate structures using the spacers 514, whereas the LDD regions may be formed prior to forming spacers 514 and, hence, extend under the spacers 514 and, in some embodiments, extend further into a portion of the semiconductor fin 506 below the dummy gate structure. The LDD regions may be formed, for example, by implanting dopants (e.g., As, P, B, In, or the like) using an ion implantation process.

In some embodiments, the source and drain regions 508 may comprise an epitaxially grown region. For example, after forming the LDD regions, the spacers 514 may be formed and, subsequently, the heavily-doped source and drain regions may be formed self-aligned to the spacers 514 by first etching the fins 506 to form recesses, and then depositing a crystalline semiconductor material in the recess by a selective epitaxial growth (SEG) process that may fill the recess and extend beyond the original surface of the fin to form a raised source-drain structure, as illustrated in FIG. 7. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁵ cm⁻² to 10²⁰ cm⁻²) of dopants may be introduced into the heavily-doped source and drain regions 508 either in situ during SEG, or by an ion implantation process performed after the SEG, or by a combination thereof.

A first interlayer dielectric (ILD) 516 is deposited over the structure. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD 516. The HKMG gate structures 512, illustrated in FIG. 7, may then be formed by first removing the dummy gate structures using one or more etching techniques, thereby creating trenches between respective spacers 514. Next, a replacement gate dielectric layer 518 comprising one more dielectrics, followed by a replacement conductive gate layer 520 comprising one or more conductive materials, are deposited to completely fill the recesses. Excess portions of the gate structure layers 518 and 520 may be removed from over the top surface of first ILD 516 using, for example a CMP process. The resulting structure, as illustrated in FIG. 7, may be a substantially coplanar surface comprising an exposed top surface of first ILD 516, spacers 514, and remaining portions of the HKMG gate layers 518 and 520 inlaid between respective spacers 514.

The gate dielectric layer 518 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the conductive gate layer 520 may be a multilayered metal gate stack comprising a barrier layer, a work function layer, and a gate-fill layer formed successively on top of gate dielectric layer 518. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, physical vapor deposition (PVD), ALD, PEALD, electrochemical plating (ECP), electroless plating and/or the like.

A second ILD layer 522 may be deposited over the first ILD layer 516, as illustrated in FIG. 7. In some embodiments, the insulating materials to form the first ILD layer 516 and the second ILD layer 522 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer 516 and the second ILD layer 522 may be deposited using any suitable method, such as CVD, physical vapor deposition (PVD), ALD, PEALD, PECVD, SACVD, FCVD, spin-on, and/or the like, or a combination thereof.

As illustrated in FIG. 7, electrodes of electronic devices formed in the substrate 502 may be electrically connected to conductive features of a first interconnect level 50A using conductive connectors (e.g., contacts 524) formed through the intervening dielectric layers. In the embodiments illustrated in FIG. 7, the contacts 524 make electrical connections to the source and drain regions 508 of FinFET 504. Contacts 524 to gate electrodes may be formed over STI regions 510, and thus are not shown in the cross-section view of FIG. 7. The contacts may be formed using photolithography techniques. For example, a patterned mask may be formed over the second ILD 522 and used to etch openings that extend through the second ILD 516 to expose a portion of gate structures 512, as well as etch openings that extend further through the first ILD 516 and the CESL (if present) liner below first ILD 516 to expose portions of the source and drain regions 508.

In some embodiments, a conductive liner may be formed in the openings in the first ILD layer 516 and the second ILD layer 522. Subsequently, the openings are filled with a conductive fill material. The liner comprises barrier metals used to reduce out-diffusion of conductive materials from the contacts 524 into the surrounding dielectric materials. In some embodiments, the liner may comprise two barrier metal layers. The first barrier metal comes in contact with the semiconductor material in the source and drain regions 508 and may be subsequently chemically reacted with the heavily-doped semiconductor in the source and drain regions 508 to form a low resistance ohmic contact, after which the unreacted metal may be removed. For example, if the heavily-doped semiconductor in the source and drain regions 508 is silicon or silicon-germanium alloy semiconductor, then the first barrier metal may comprise Ti, Ni, Pt, Co, other suitable metals, or their alloys. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the second ILD 522. The resulting conductive plugs extend into the first and second ILD layers 516 and 522 and constitute contacts 524 making physical and electrical connections to the electrodes of electronic devices, such as the tri-gate FinFET 504 illustrated in FIG. 7.

As illustrated in FIG. 7, multiple interconnect levels may be formed, stacked vertically above the contact plugs 524 formed in the first and second ILD layers 516 and 522, in accordance with a back end of line (BEOL) scheme adopted for the integrated circuit design. In the BEOL scheme illustrated in FIG. 7, various interconnect levels have similar features. However, it is understood that other embodiments may utilize alternate integration schemes wherein the various interconnect levels may use different features. For example, the contacts 524, which are shown as vertical connectors, may be extended to form conductive lines which transport current laterally.

In this disclosure, the second interconnect level comprises conductive vias and lines embedded in an inter-metal dielectric (IMD) layer. In addition to providing insulation between various conductive elements, an IMD layer may include one or more dielectric etch stop layers to control the etching processes that form openings in the IMD layer. Generally, vias conduct current vertically and are used to electrically connect two conductive features located at vertically adjacent levels, whereas lines conduct current laterally and are used to distribute electrical signals and power within one level. In the BEOL scheme illustrated in FIG. 7, conductive vias 53A connect contacts 524 to conductive lines 54A and, at subsequent levels, vias connect lower lines to upper lines (e.g., a pair of lines 54A and 54B can be connected by via 53B). Other embodiments may adopt a different scheme. For example, vias 53A may be omitted from the second level and the contacts 524 may be configured to be directly connected to lines 54A.

The first interconnect level 50A may be formed using, for example, a dual damascene process flow. First, a dielectric stack used to form IMD layer 55A may be deposited using one or more layers of the dielectric materials listed in the description of the first and second ILD layers 516 and 522. In some embodiments, IMD layer 55A includes an etch stop layer (not shown) positioned at the bottom of the dielectric stack. The etch stop layer comprises one or more insulator layers (e.g., SiN, SiC, SiCN, SiCO, CN, combinations thereof, or the like) having an etch rate different than an etch rate of an overlying material. The techniques used to deposit the dielectric stack for IMD may be the same as those used in forming the first and second ILD layers 516 and 522.

Appropriate photolithography and etching techniques (e.g., anisotropic RIE employing fluorocarbon chemistry) may be used to pattern the IMD layer 55A to form openings for vias and lines. The openings for vias may be vertical holes extending through IMD layer 55A to expose a top conductive surface of contacts 524, and openings for lines may be longitudinal trenches formed in an upper portion of the IMD layer 55A. In some embodiments, the method used to pattern holes and trenches in IMD layer 55A utilizes a via-first scheme, wherein a first photolithography and etch process form holes for vias, and a second photolithography and etch process form trenches for lines. Other embodiments may use a different method, for example, a trench-first scheme, or an incomplete via-first scheme, or a buried etch stop layer scheme. The etching techniques may utilize multiple steps. For example, a first main etch step may remove a portion of the dielectric material of IMD layer 55A and stop on an etch stop dielectric layer. Then, the etchants may be switched to remove the etch stop layer dielectric materials. The parameters of the various etch steps (e.g., chemical composition, flow rate, and pressure of the gases, reactor power, etc.) may be tuned to produce tapered sidewall profiles with a desired interior taper angle.

Several conductive materials may be deposited to fill the holes and trenches forming the conductive features 53A and 54A of the first interconnect level 50A. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the vias 53A and lines 54A comprises one or more layers of TaN, Ta, TiN, Ti, Co, or the like, or combinations thereof. The conductive fill layer in the vias 53A and lines 54A may comprise metals such as Cu, Al, W, Co, Ru, or the like, or combinations thereof, or multi-layers thereof. The conductive materials used in forming the conductive features 53A and 54A may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like).

Any excess conductive material over the IMD 55A outside of the openings may be removed by a planarizing process (e.g., CMP) thereby forming a top surface comprising dielectric regions of IMD 55A that are substantially coplanar with conductive regions of the conductive lines 54A. The planarization step embeds the conductive vias 53A and conductive lines 54A into IMD 55A, as illustrated in FIG. 7.

The interconnect level positioned vertically above the first interconnect level 50A in FIG. 7, is the second interconnect level 50B. In some embodiments, the structures of the various interconnect levels (e.g., the first interconnect level 50A and the second interconnect level 50B) may be similar. In the example illustrated in FIG. 7, the second interconnect level 50B comprises conductive vias 53B and conductive lines 54B embedded in an insulating film IMD 55B having a planar top surface. The materials and processing techniques described above in the context of the first interconnect level 50A may be used to form the second interconnect level 50B and subsequent interconnect levels.

Although an example electronic device (FinFET 504) and example interconnect structures making connections to the electronic device are described, it is understood that one of ordinary skill in the art will appreciate that the above examples are provided for illustrative purposes only to further explain applications of the present embodiments, and are not meant to limit the present embodiments in any manner.

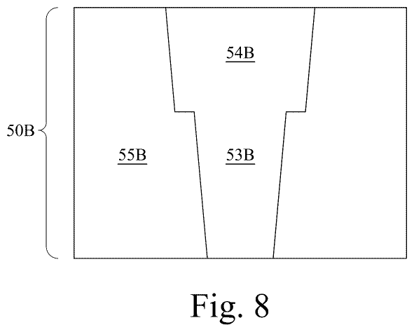

FIG. 8 illustrates a zoomed-in view of a region 501 of FIG. 7, showing an interconnect level 50B at an initial stage of fabrication of the capacitive synaptic cell. In FIG. 6, a via 53B and a conductive line 54B are shown embedded in an insulating film IMD 55B. The conductive line 54B can serve as a word line or bit line for the capacitive synaptic cell. The top dielectric surface of IMD 55B is shown to be substantially coplanar with the top conductive surface of conductive line 54B, within process variations.

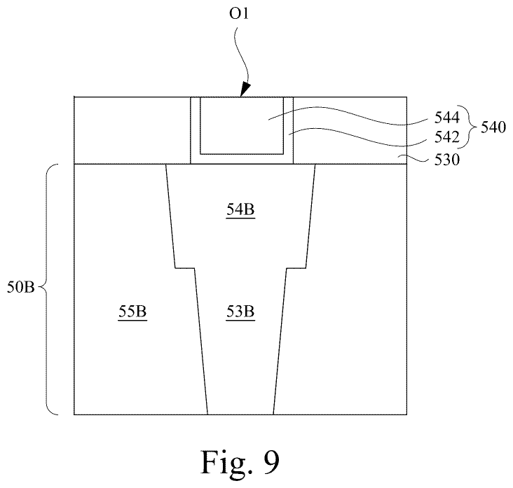

In FIG. 9, an inter-metal dielectric (IMD) layer 530 is formed over the interconnect level 50B. In some embodiments, the IMD layer 530 may include silicon oxide, silicon nitride, silicon oxynitride, tetraethoxysilane (TEOS) oxide, phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The IMD layer 530 may be formed using, for example, CVD, ALD, spin-on-glass (SOG) or other suitable techniques.

Next, a bottom electrode via (BEVA) structure 540 is formed in the IMD layer 530 to make contact with the conductive line 54B. In some embodiments, formation of the BEVA structure 540 includes patterning the IMD layer 530 to form a via opening O1 extending through the IMD layer 530 to expose the conductive line 102, conformally depositing a barrier material lining sidewalls and bottom surface of the via opening O1, depositing a fill metal overfilling the via opening O1, followed by performing a chemical mechanical polish (CMP) process to remove excess fill metal and excess barrier material outside the via opening O1, while leaving the barrier material in the via openings O1 to serve as the barrier layer 542 lining the via opening O1, and leaving the fill metal in the via opening O1 to serve as the fill metal structure 544 with an underside cupped by the barrier layer 542.

In some embodiments, the barrier layer 542 assists with the deposition of the fill metal structure 544 and helps to reduce out-diffusion of a metal material of the fill metal structure 544. In some embodiments, the barrier layer 542 includes titanium (Ti), titanium nitride (TiN), tantalum (Ta), tantalum nitride (TaN), or another suitable material. The fill metal structure 544 includes a conductive material, such tungsten (W), copper (Cu), aluminum (Al), ruthenium (Ru), cobalt (Co), molybdenum (Mo), nickel (Ni), or other suitable conductive materials.

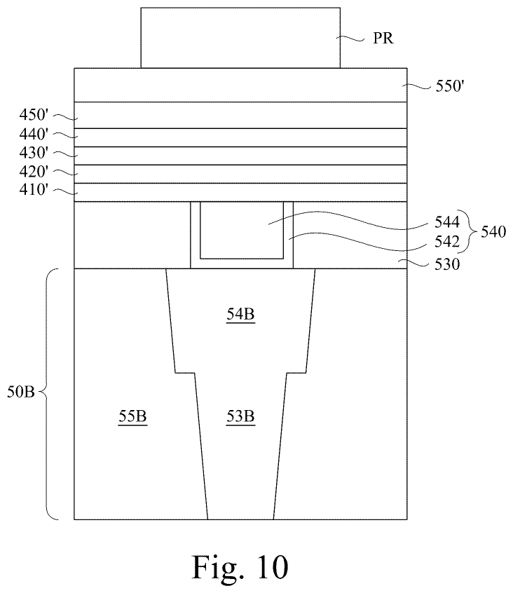

In FIG. 10, a multilayer stack of FeCAP materials are deposited in sequence over the BEVA structure 540. In some embodiments, the multilayer stack of FeCAP materials can be formed by, for example, depositing a bottom electrode layer 410′ over the BEVA structure 540, followed by depositing a ferroelectric layer 420′ over the bottom electrode layer 410′, followed by depositing a high-k dielectric layer 430′ over the ferroelectric layer 420′, followed by depositing an oxide semiconductor layer 440′ over the high-k dielectric layer 430′, and followed by depositing a top electrode layer 450′ over the oxide semiconductor layer 440′. Materials, thicknesses and other details about the bottom electrode layer 410′, ferroelectric layer 420′, high-k dielectric layer 430′, oxide semiconductor layer 440′, and top electrode layer 450′ are respectively the same as that of the bottom electrode 410, ferroelectric layer 420, high-k dielectric layer 430, oxide semiconductor layer 440, and top electrode 450 discussed previously with respect to FIG. 4, and thus are not repeated for the sake of brevity. In some embodiments, one or more of the bottom electrode layer 410′, the ferroelectric layer 420′, the high-k dielectric layer 430′, the oxide semiconductor layer 440′, and the top electrode layer 450′ are deposited by using 410 by using any suitable deposition method, e.g., chemical vapor deposition (CVD), plasma-enhanced CVD (PECVD), physical vapor deposition (PVD), atomic layer deposition (ALD), plasma-enhanced ALD (PEALD), or the like.

After the multilayer stack of FeCAP materials are deposited over the BEVA structure 540, a hard mask layer 550′ is deposited over the top electrode layer 450′ by using a suitable deposition technique, such as CVD or PECVD. In some embodiments, the hard mask layer 550′ includes a different material than the multilayer stack of FeCAP materials. For example, the hard mask layer 550′ includes silicon oxynitride (SiON), silicon nitride, the like, or other suitable dielectric materials. Next, a patterned photoresist layer PR is formed over the hard mask layer 550′ by using suitable photolithography processes.

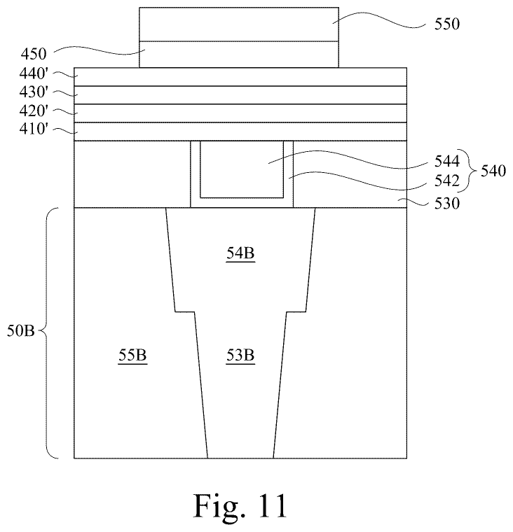

In FIG. 11, the hard mask layer 550′ is patterned into a patterned hard mask 550 by using the photoresist layer PR as an etch mask, followed by patterning the top electrode layer 450′ into the top electrode 450 by using the patterned hard mask 550 as an etch mask. In some embodiments, the hard mask layer 550′ and the top electrode layer 450′ are patterned in a single continuous etching step. In some other embodiments, the hard mask layer 550′ and the top electrode layer 450′ are patterned in different etching steps with different etchant chemistries.

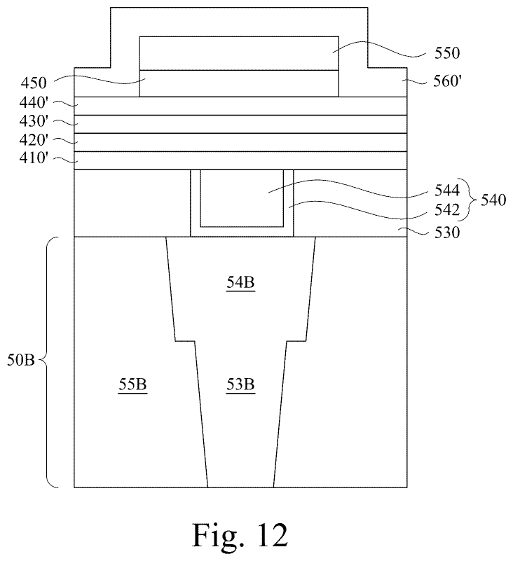

In FIG. 12, a spacer layer 560′ is deposited over the patterned hard mask 550. The spacer layer 560′ in some embodiments may include SiN, but in other embodiments may include SiC, SiON, silicon oxycarbide (SiOC), the like, and/or combinations thereof. The spacer layer 560′ may be formed using CVD, PVD, ALD, the like, and/or combinations thereof. The spacer layer 560′ may be formed as a substantially conformal layer, and hence a thickness of vertical portions of the spacer layer 560 on vertical sidewalls of the top electrode 450 and patterned hard mask 550 is substantially the same as a thickness of horizontal portion of the spacer layer 560′.

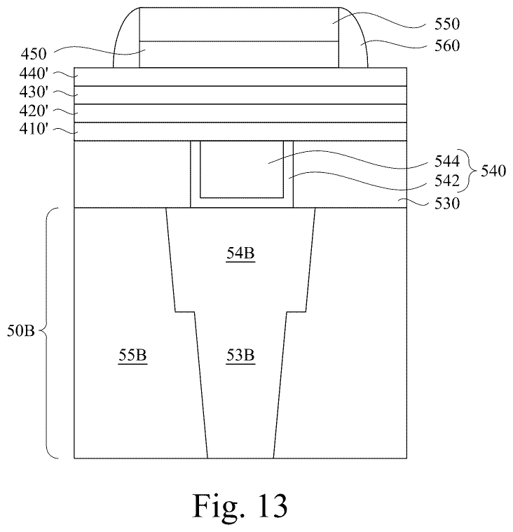

In FIG. 13, an etching process is performed on the spacer layer 560′ to remove horizontal portions from the oxide semiconductor layer 440′, while leaving portions of the spacer layer 560′ on sidewalls of the top electrode 450 and the hard mask 550 to serve as sidewall spacers 560. This step can be interchangeably referred to as a self-aligned spacer (SPA) etching process, because the resultant sidewall spacers 560 can be formed self-aligned to the stack of top electrode 450 and the hard mask 550 without an additional photolithography process. The SPA etching process may include a selective anisotropic dry etch process, which etches the spacer layer 560′ at a faster etch rate than etching the hard mask 550 and the oxide semiconductor layer 440′.

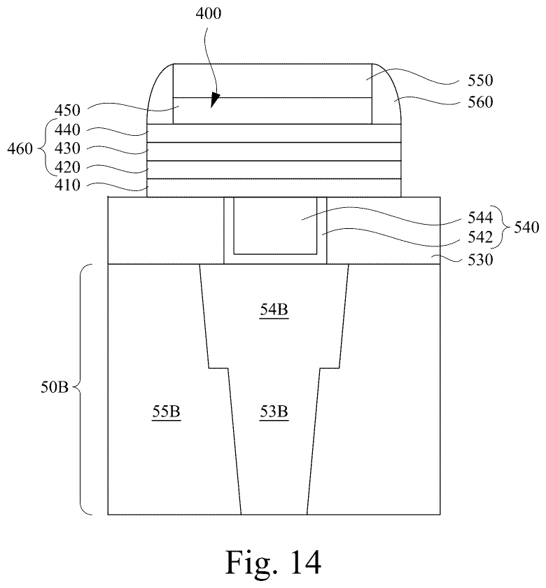

In FIG. 14, the oxide semiconductor layer 440′, the high-k dielectric layer 430′, the ferroelectric layer 420′, and the bottom electrode layer 410′ are patterned into the patterned oxide semiconductor layer 440, the patterned high-k dielectric layer 430, the patterned ferroelectric layer 420, and the patterned bottom electrode 410, by one or more etching processes using the hard mask 550 and the side wall spacers 560 as an etch mask. The resultant bottom electrode 410, ferroelectric layer 420, high-k dielectric layer 430, oxide semiconductor layer 440, and the top electrode 450 can collectively serve as a FeCAP structure 400 that can function as a capacitive synaptic cell in a neural network as illustrated in FIGS. 1-2.

The step of patterning the layers 410′-440′ can be interchangeably referred to as a self-aligned etching process, because the resultant oxide semiconductor layer 440, high-k dielectric layer 430, ferroelectric layer 420, and bottom electrode 410 can be formed self-aligned to the footprint of the hard mask 550 and sidewall spacers 560 without an additional photolithography process. By way of example and not limitation, the self-aligned etching process may include a selective anisotropic dry etch process, which etches materials of layers 410′-440′ at a faster etch rate than etching the hard mask layer 550 and sidewall spacers 560. In some embodiments, the self-aligned etching process includes a plasma dry etching process using a chlorine-based or fluorine-based chemistry. Because the high-k dielectric layer 430, ferroelectric layer 420, and bottom electrode 410 are formed the hard mask 550 and sidewall spacers 560 as an etch mask, the high-k dielectric layer 430, ferroelectric layer 420, and bottom electrode 410 have a width greater than a width of the hard mask 550 and the top electrode 450.

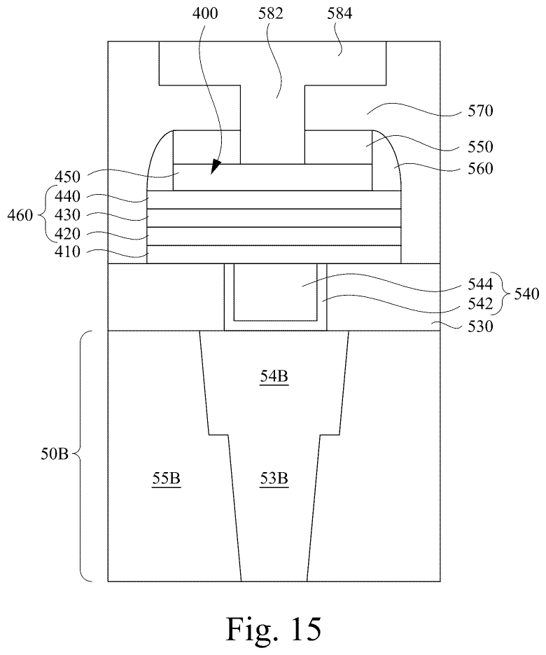

In FIG. 15, an IMD layer 570 is deposited over the FeCAP structure 400. In some embodiments, the IMD layer 530 may include silicon oxide, silicon nitride, silicon oxynitride, tetraethoxysilane (TEOS) oxide, phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The IMD layer 530 may be formed using, for example, CVD, ALD, spin-on-glass (SOG) or other suitable techniques.

Next, a top electrode via (TEVA) structure 582 and a conductive line 584 is formed in the IMD layer 570 by using, for example, a dual damascene process flow. For example, appropriate photolithography and etching techniques (e.g., anisotropic RIE employing fluorocarbon chemistry) may be used to pattern the IMD layer 570 to form openings for the TEVA structure 582 and the conductive line 584. The opening for the TEVA structure 582 may be a vertical hole extending through IMD layer 570 and the hard mask 550 to expose the top electrode 450, and the opening for the conductive line 584 may be longitudinal trenches formed in an upper portion of the IMD layer 570. In some embodiments, the method used to pattern holes and trenches in IMD layer 570 utilizes a via-first scheme, wherein a first photolithography and etch process form the hole for the TEVA structure 582, and a second photolithography and etch process form the trench for conductive line 584. Other embodiments may use a different method, for example, a trench-first scheme. Once the hole and trench for the TEVA structure 582 and the conductive line 584 are formed, one or more conductive materials are then deposited to overfill the hole and trench, followed by a CMP process to remove excess conductive materials outside the hole and trench, while leaving the remaining conductive materials to serve as the TEVA structure 582 and the conductive line 584. In some embodiments, the TEVA structure 582 and the conductive line 584 includes a diffusion barrier layer such as TaN, Ta, TiN, Ti, Co, the like, or combinations thereof, and a fill metal layer such as Cu, Al, W, Co, Ru, the like, or combinations thereof. The conductive line 584 can serve as a bit line or word line electrically coupled to the top electrode 450 of the FeCAP structure 400 through the TEVA structure 582.

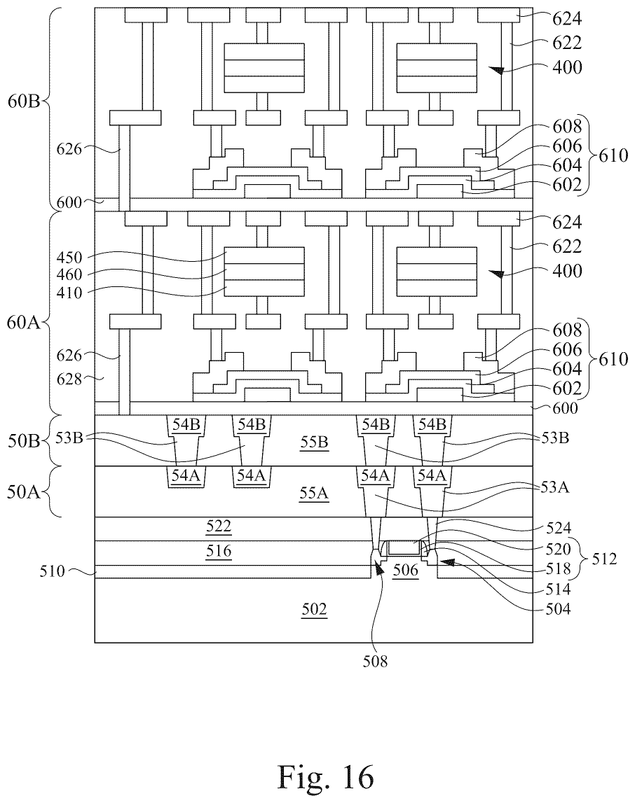

FIG. 16 is a cross-sectional view of an integrated circuit structure in accordance with some embodiments of the present disclosure. The IC structure generally includes the same structure as the IC structure 500 illustrated in FIG. 7, except that the IC structure further includes one or more transistor-containing interconnect levels (e.g., levels 60A and 60B) each including one or more BEOL transistors 610 and one or more FeCAP structures 400 disposed over the one or more BEOL transistors 610. The transistor-containing interconnect level 60A is spaced apart from the underlying interconnect layer 50B by an inter-level dielectric layer 600, and the transistor-containing interconnect level 60B is spaced apart from the underlying transistor-containing interconnect level 60A by another inter-level dielectric layer 600.

In some embodiments, the FeCAP structures 400 in each transistor-containing interconnect level can serve as synaptic cells for neural network, and each FeCAP structure 400 includes the bottom electrode 410, the top electrode 450, and a capacitance-switchable multilayer stack 460 disposed between the bottom and top electrodes 410, 450. The capacitance-switchable multilayer stack 460 includes the ferroelectric layer 420, the high-k dielectric layer 430, and the oxide semiconductor layer 440 as illustrated in FIG. 15. These layers are not illustrated in the multilayer stack 460 in FIG. 16 for the sake of clarity.

In some embodiments, one or more BEOL transistors 610 can serve for the neural network, e.g., serving as transistors of neuron circuits and/or transistors of WL multiplexers (denoted by “MUX” in FIG. 2). In some embodiments, one or more BEOL transistors 610 are thin-film transistors each including a back gate structure 602 formed over the inter-level dielectric layer 600 by using suitable deposition and etching techniques, a gate dielectric layer 604 formed over the back gate structure 602 by using suitable deposition and etching techniques, a semiconductor layer 606 formed over the gate dielectric layer 604 by using suitable deposition and etching techniques, and source/drain metal electrodes 608 over separated regions of the semiconductor layer 606 by using suitable deposition and etching techniques. In some embodiments, the semiconductor layer 606 is formed of oxide semiconductor, such as indium gallium zinc oxide (IGZO), zinc oxide (ZnO), Indium Zinc Oxide (IZO), gallium zinc oxide (GZO), or the like. In some other embodiments, the semiconductor layer 606 is formed of polysilicon.

The transistor-containing interconnect levels 60A and 60B each include vertically extending vias 622 and conductive lines 624 laterally extending over the corresponding vias 622. The vias 622 and conductive lines 624 may be formed in one or more dielectric layers 628 using, for example, a dual damascene process flow. In some embodiments, the transistor-containing interconnect levels 60A and 60B each including one or more through vias 626 extending through the corresponding inter-level dielectric layer 600 to provide electrical connections between transistor-containing interconnect levels 60A and 60B, and electrical connections between the transistor-containing interconnect level 60A and the underlying interconnect layers 50A, 50B and front-end-of-line (FEOL) transistors 504. In some embodiments, the BEOL transistors 610 in the transistor-containing interconnect level 60A are of neurons in a pre-neuron layer (e.g., input neuron layer 110/210 as illustrated in FIGS. 1-2), the BEOL transistors 610 in the transistor-containing interconnect level 60B are of neurons in a post-neuron layer (e.g., hidden neuron layer 120/220 as illustrated in FIGS. 1-2), and FeCAP structures 400 in the interconnect levels 60A and/or 60B serve as synaptic cells connecting the neurons in the pre-neuron layer to the neurons in the post-neuron layer.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that a multilayer stack between FeCAP top and bottom electrodes allows for improving the memory window of the FeCAP. Another advantage is that the data retention performance and endurance of the FeCAP can be improved.

In some embodiments, a capacitor structure includes a bottom electrode, a top electrode, and a multilayer stack disposed between the bottom electrode and the top electrode. The multilayer stack has a capacitance value switchable between at least two capacitance states. The multilayer stack includes a ferroelectric layer disposed between the bottom electrode and the top electrode, and an oxide semiconductor layer over the ferroelectric layer. In some embodiments, the ferroelectric layer comprises a tetragonal crystalline phase and an orthorhombic crystalline phase. In some embodiments, the multilayer stack further includes a high-k dielectric layer between the ferroelectric layer and the oxide semiconductor layer. In some embodiments, the high-k dielectric layer has a thickness less than a thickness of the ferroelectric layer and/or a thickness of the oxide semiconductor layer. In some embodiments, the oxide semiconductor layer is in contact with the top electrode, and the ferroelectric layer is spaced apart from the top electrode. In some embodiments, the top electrode has a width less than a width of the oxide semiconductor layer. In some embodiments, the capacitor structure further includes a hard mask over the top electrode, and the hard mask has a width less than a width of the oxide semiconductor layer.

In some embodiments, a neural network circuit includes a plurality of first electronic neurons, a plurality of second electronic neurons, and a weight matrix including a plurality of synaptic cells each connecting one of the plurality of first electronic neurons to one of the second electronic neurons. The synaptic cells each include a capacitor having a bottom electrode, a multilayer stack, and a top electrode over the multilayer stack. The multilayer stack has a capacitance value switchable between at least two capacitance states. The multilayer stack has a ferroelectric layer interposing between the bottom electrode and the top electrode, and a high-k dielectric layer over the ferroelectric layer. In some embodiments, the high-k dielectric layer is thinner than the ferroelectric layer. In some embodiments, the multilayer stack further comprises an oxide semiconductor layer. In some embodiments, the oxide semiconductor layer is spaced apart from the ferroelectric layer by the high-k dielectric layer. In some embodiments, the oxide semiconductor layer is thicker than the high-k dielectric layer. In some embodiments, the high-k dielectric layer has opposite surfaces respectively in contact with the oxide semiconductor layer and the ferroelectric layer. In some embodiments, the capacitor of each of the synaptic cells has a top electrode and a bottom electrode sandwiching the multilayer stack, and the top electrode and the bottom electrode have different materials.

In some embodiments, a method includes forming a bottom electrode layer over a substrate, forming a ferroelectric layer over the bottom electrode layer, forming an oxide semiconductor layer over the ferroelectric layer, forming a top electrode layer over the oxide semiconductor layer, patterning the top electrode layer into a top electrode, forming sidewall spacers on opposite sidewalls of the top electrode, and after forming the sidewall spacers, patterning the oxide semiconductor layer and the ferroelectric layer. In some embodiments, the method further includes forming a high-k dielectric layer over the ferroelectric layer prior to forming the oxide semiconductor layer. In some embodiments, the high-k dielectric layer is thinner than the ferroelectric layer. In some embodiments, the method further includes after forming the sidewall spacers, patterning the bottom electrode layer into a bottom electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A capacitor structure, comprising:
a bottom electrode;
a top electrode; and
a multilayer stack disposed between the bottom electrode and the top electrode, the multilayer stack comprising:
a ferroelectric layer disposed between the bottom electrode and the top electrode; and
an oxide compound layer over the ferroelectric layer.

2. The capacitor structure of claim 1, wherein the ferroelectric layer comprises a tetragonal crystalline phase.

3. The capacitor structure of claim 2, wherein the ferroelectric layer further comprises an orthorhombic crystalline phase.

4. The capacitor structure of claim 1, wherein the multilayer stack further comprises:
a high-k dielectric layer between the ferroelectric layer and the oxide compound layer.

5. The capacitor structure of claim 4, wherein the high-k dielectric layer has a thickness less than a thickness of the ferroelectric layer.

6. The capacitor structure of claim 4, wherein the high-k dielectric layer has a thickness less than a thickness of the oxide compound layer.

7. The capacitor structure of claim 1, wherein the oxide compound layer is in contact with the top electrode.

8. The capacitor structure of claim 1, wherein the ferroelectric layer is spaced apart from the top electrode.

9. The capacitor structure of claim 1, wherein the top electrode has a width less than a width of the oxide compound layer.

10. A neural network circuit, comprising:
a plurality of first electronic neurons;
a plurality of second electronic neurons; and
a weight matrix comprising a plurality of synaptic cells each connecting one of the plurality of first electronic neurons to one of the second electronic neurons, the plurality of synaptic cells each comprising a capacitor comprising a bottom electrode, a multilayer stack over the bottom electrode, and a top electrode over the multilayer stack, the multilayer stack comprising a ferroelectric layer interposing between the bottom electrode and the top electrode, and a high-k dielectric layer over the ferroelectric layer.

11. The neural network circuit of claim 10, wherein the high-k dielectric layer is thinner than the ferroelectric layer.

12. The neural network circuit of claim 10, wherein the multilayer stack further comprises an oxide compound layer.

13. The neural network circuit of claim 12, wherein the oxide compound layer is spaced apart from the ferroelectric layer by the high-k dielectric layer.

14. The neural network circuit of claim 12, wherein the oxide compound layer is thicker than the high-k dielectric layer.

15. The neural network circuit of claim 12, wherein the high-k dielectric layer has opposite surfaces respectively in contact with the oxide compound layer and the ferroelectric layer.

16. The neural network circuit of claim 10, wherein the capacitor of each of the plurality of synaptic cells has a top electrode and a bottom electrode sandwiching the multilayer stack, and wherein the top electrode and the bottom electrode have different materials.

17. A method, comprising:
forming a bottom electrode layer over a substrate;
forming a ferroelectric layer over the bottom electrode layer;
forming an oxide compound layer over the ferroelectric layer;
forming a top electrode layer over the oxide compound layer;
patterning the top electrode layer into a top electrode;
forming sidewall spacers on opposite sidewalls of the top electrode; and
after forming the sidewall spacers, patterning the oxide compound layer and the ferroelectric layer.

18. The method of claim 17, further comprising:
forming a high-k dielectric layer over the ferroelectric layer prior to forming the oxide compound layer.

19. The method of claim 18, wherein the high-k dielectric layer is thinner than the ferroelectric layer.

20. The method of claim 17, further comprising:
after forming the sidewall spacers, patterning the bottom electrode layer into a bottom electrode.
